(19) United States
(12) Patent Application Publication
(10) Pub. No.: US 2024/0170399 A1
(43) Pub. Date: May 23, 2024

(54) SEMICONDUCTOR DEVICE WITH LINES AND VIAS WITH VARIABLE HEIGHT FOR LOCAL RC OPTIMIZATION

(71) Applicant: International Business Machines Corporation, Armonk, NY (US)

(72) Inventors: Nicholas Anthony Lanzillo, Wynantskill, NY (US); Koichi Motoyama, Clifton Park, NY (US); Lawrence A. Clevenger, Saratoga Springs, NY (US)

(21) Appl. No.: 18/057,884

(22) Filed: Nov. 22, 2022

(51) Int. Cl. H01L 23/528; H01L 21/768; H01L 23/522

(52) U.S. Cl. CPC H01L 23/5283; H01L 21/76816; H01L 21/76877; H01L 23/5226

(57) ABSTRACT

One or more systems, devices, and/or methods of use provided herein relate to a semiconductor device with lines and vias having variable heights. A semiconductor device can include a substrate and a first level of interconnect wiring including a plurality of metal conductive lines electrically coupled to the substrate. The semiconductor device can include a first portion of the plurality of metal conductive lines including a first height; and a second portion of the plurality of metal conductive lines including a second height. The second height can be greater than the first height. The first height and the second height can be different by an amount larger than a fabrication variance for the semiconductor device. The second height can be different from the first height by at least about 25%.

### BACKGROUND

One or more embodiments described herein relate generally to optimizing semiconductor devices with respect to the various connected components. Embodiments relate to varying heights of one or more interconnect layers and vias of a semiconductor device, and more specifically, to systems and methods to facilitate layout-dependent external collector resistance (RC) optimization of the interconnected layers.

### SUMMARY

The following presents a summary to provide a basic understanding of one or more embodiments described herein. This summary is not intended to identify key or critical elements or delineate any scope of the particular embodiments or any scope of the claims. The sole purpose of the summary is to present concepts in a simplified form as a prelude to the more detailed description that is presented later. In one or more embodiments described herein, systems, devices, and/or methods, that facilitate layout dependent RC optimization for a semiconductor device are described.

According to an embodiment, a semiconductor device can comprise a substrate and a first level of interconnect wiring including a plurality of metal conductive lines electrically coupled to the substrate. A first portion of the plurality of metal conductive lines can include a first height; and a second portion of the plurality of metal conductive lines can include a second height. Further, the second height can be greater than the first height.

According to another embodiment, a semiconductor device can comprise a substrate and a first level of interconnect wiring including a plurality of metal conductive lines electrically coupled to the substrate. The semiconductor device can further include a second level of interconnect wiring including a second plurality of metal conductive lines having a first portion and a second portion. Additionally, the semiconductor device can include a plurality of vias connecting the first level of interconnect wiring to the second level of interconnect wiring. Further, at least one of the first level of interconnect wiring and the second level of interconnect wiring can include a variable height, and the plurality of vias can include variable heights.

According to yet another embodiment, a method for fabricating a semiconductor device by a fabrication system can comprise providing, by the fabrication system, a substrate; a first level of interconnect wiring including a first plurality of metal conductive lines electrically coupled to the substrate; and a second level of interconnect wiring including a second plurality of metal conductive lines electrically coupled to the substrate. The method for fabricating the semiconductor device can additionally comprise etching, by the fabrication system, a first portion of at least one of the first plurality of metal conductive lines and the second plurality of metal conductive lines to include a first height. Further, the method can include etching, by the fabrication system, a second portion of the at least one of the first plurality of metal conductive lines and the second plurality of metal conductive lines to include a second height. Additionally, the method can include etching, by the fabrication system, the other of the at least one of the first plurality of metal conductive lines and the second plurality of metal conductive lines. The method for fabricating a semiconductor device can include disposing, by the fabrication system, a plurality of vias connecting the first level of interconnect wiring to the second level of interconnect wiring; and the second height can be different than the first height.

### DESCRIPTION OF THE DRAWINGS

FIG. 1 illustrates a cross-sectional view of an example, non-limiting semiconductor device comprising lines and vias with variable height, in accordance with one or more embodiments described herein.

FIG. 2 illustrates a cross-sectional view of another example, non-limiting semiconductor device comprising lines and vias with variable height, in accordance with one or more embodiments described herein.

FIG. 3 illustrates a top view of another example, non-limiting semiconductor device comprising lines and vias with variable height, in accordance with one or more embodiments described herein.

FIGS. 4A-4I illustrate cross-sectional views of another example, non-limiting semiconductor device comprising lines and vias with variable height, in accordance with one or more embodiments described herein.

FIGS. 5A-5G illustrate cross-sectional views of another example, non-limiting semiconductor device comprising lines and vias with variable height, in accordance with one or more embodiments described herein.

FIGS. 6A and 6B illustrate flow diagrams of an example, non-limiting methods for fabricating a semiconductor device comprising lines and vias with variable height, in accordance with one or more embodiments described herein.

FIG. 7 illustrates a block diagram of an example, non-limiting operating environment in which one or more embodiments described herein can be facilitated.

### DETAILED DESCRIPTION

The following detailed description is merely illustrative and is not intended to limit embodiments or application or uses of embodiments. Furthermore, there is no intention to be bound by any expressed or implied information presented in the preceding Background or Summary sections, or in this Detailed Description section.

Discussion is provided herein relative to configuration, including fabrication, of an electronic structure that can comprise and/or be comprised by a controller, payload and/or other chip-based structure. In one or more embodiments, the electronic structure can be configured for use in a quantum system. However, as there are many uses for devices comprising silicon chips, the discussion herein need not apply solely to quantum computer electronics, but can also apply to many other control, radio, radar, cryogenic and/or signal-based applications, among others. Description and discussion herein is therefore not limited to use in a quantum computing system.

In some cases, it can be desirable to optimize conductive lines and/or vias of a semiconductor to cause optimal performance of connected devices (e.g., inverters, transistors, etc.). One or more various devices can be connected to the semiconductor device, and the one or more various devices can also be sensitive to resistance values and/or capacitance values of the connected lines. For example, some devices can perform more efficiently/accurately if connected to a conductive line with an optimized resistance or capacitance value. In examples, for conductive lines to be connected with components sensitive to capacitance, it can be desirable to connect the respective component to a conductive line with low capacitance. Similarly, for conductive lines to be connected with components sensitive to resistance, it can be desirable to connect the respective component to a conductive line with low resistance. Given the desire to optimize semiconductors for connected devices and/or components, the capacitance and resistance of conducive lines/vias can be varied by the height of the conductive line/via.

It can be desirable to optimize the performance of connected devices by utilizing lines and vias including variable height. The height of a line and/or via can linearly affect the performance of the one or more connected devices (e.g., capacitance/resistance and height can have a liner relationship). One or more conductive lines of a plurality of conductive lines can include a variable height. Moreover, multiple devices can be optimally connected with a plurality of conductive lines by varying the height at different portions of the plurality of conductive lines so the resistance values and capacitance values align with the optimal constraints of the connected device.

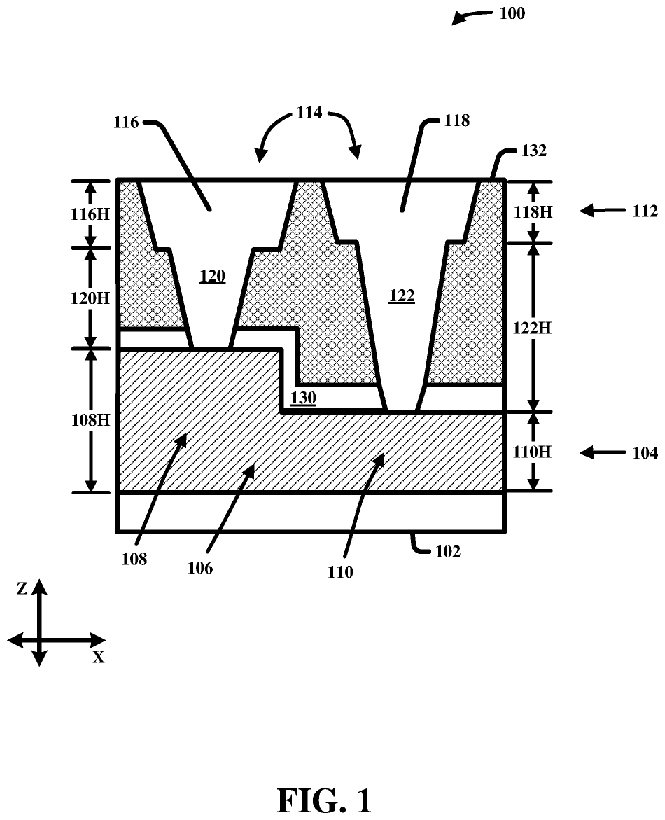

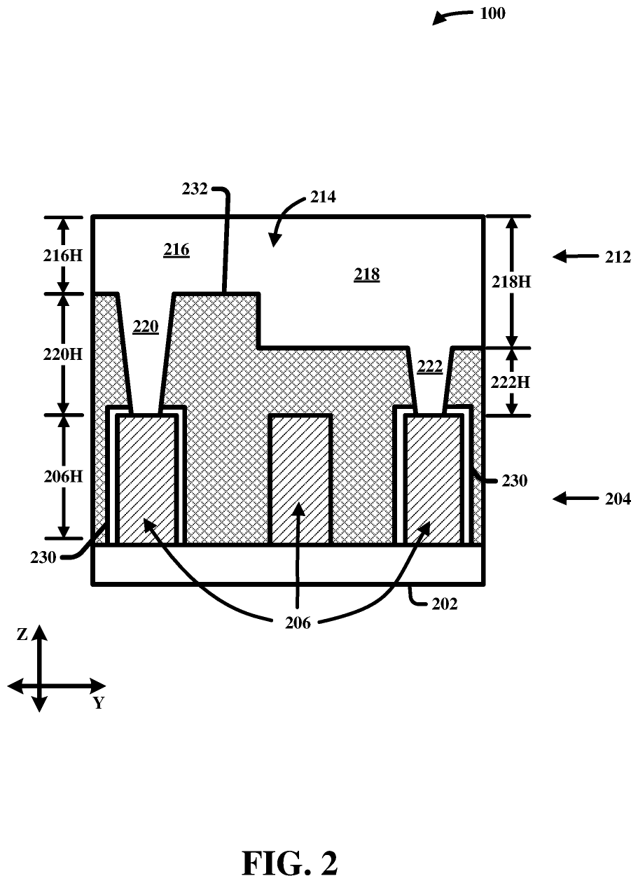

Additional description of functionalities will be further described below with reference to the example embodiments of FIGS. 1 and 2, where repetitive description of like elements and/or processes employed in respective embodiments is omitted for sake of brevity. The semiconductor device can comprise a first level of interconnect wiring including a plurality of metal conductive lines electrically coupled to the substrate. The plurality of metal conductive lines can include a first portion and a second portion. The first portion and the second portion can include varying heights such as to accommodate for the optimum connection between the plurality of metal conductive lines and the connected device (e.g., to maximize the device performance in terms of capacitance and resistance). The first portion be substantially different in height than the second portion. For example, the difference in height can be larger than a fabrication variance for the semiconductor device (e.g., a fabrication variance can be about 1-3 nm). Further, the difference between the heights can be about 25% or more or less.

In embodiments, FIG. 1 illustrates a cross-sectional view of an example, non-limiting semiconductor device 100 that can address the challenges of layout dependent RC optimization. Further, the semiconductor device 100 can include a substrate 102 and a first level of interconnect wiring 104 including a plurality of metal conductive lines 106 electrically coupled to the substrate 102 (e.g., which can be one or more various electrical components connected with the semiconductor device 100). The plurality of metal conductive lines 106 can include a first portion 108 and a second portion 110. The first portion 108 and the second portion 110 can be formed via a subtractive process, which can result in the first portion 108 and the second portion 110 having subtractive profiles. The first portion 108 can be disposed substantially adjacent to the second portion 110 (e.g., in the X-direction). Further, the plurality of metal conductive lines 106 can include a variable height. In examples, the height of the plurality of metal conductive lines 106 can vary along the length of the first level of interconnect wiring 104. For example and without limitation, varying the heights of the plurality of metal conductive lines 106 can, in response, vary the resistive and capacitive properties of the plurality of metal conductive lines 106. Such heights can be selected to optimize electrical connections and performance between the plurality of metal conductive lines 106 and one or more devices connected to the semiconductor device 100.

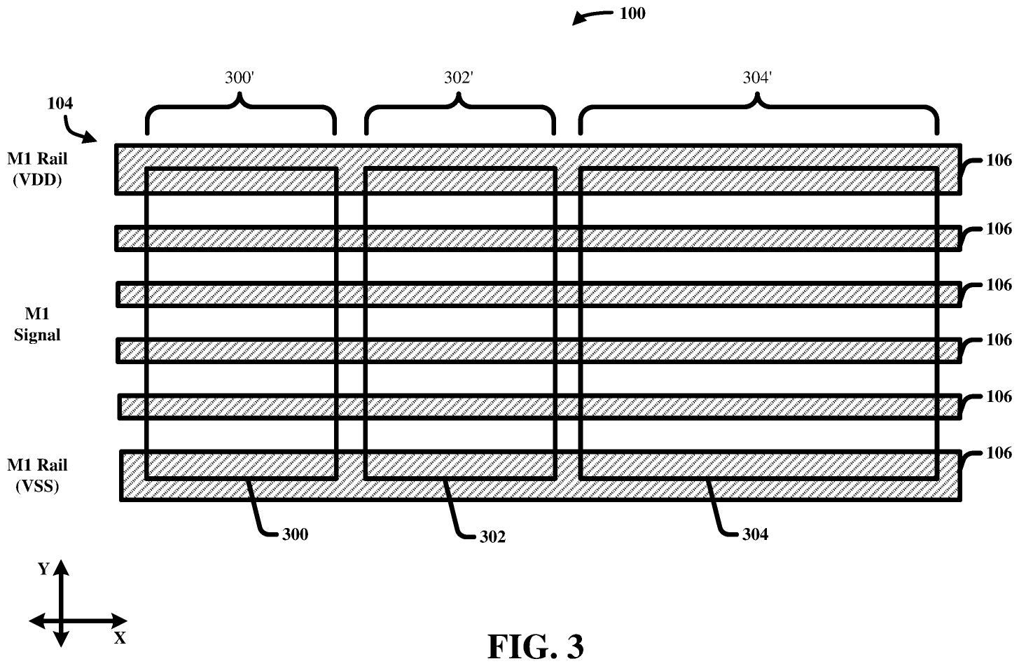

Further, lines of the plurality of metal conductive lines 106 can include taller heights (e.g., greater heights) to optimize connections based on the resistance properties of the line. Additionally, lines of the plurality of metal conductive lines 106 can include shorter (e.g., lesser heights) to optimize connections based on capacitive properties of the line (further illustrated in FIG. 3). The first portion 108 of the plurality of metal conductive lines 106 can include a first height 108H, and the second portion 110 can include a second height 110H. With examples, the first height 108H can be different than the second height 110H. For example and without limitation, the difference between the first height 108H and the second height 110H can be about 25% or more. In examples, the difference between the first height 108H and the second height 110H can be greater than a fabrication variance for the semiconductor device 100, such as to facilitate optimized performance of the one or more devices electrically connected with the plurality of metal conductive lines 106. The first height 108H and the second height 110H can be determined from a bottom of the first level of interconnect wiring 104 (e.g., alternatively, the same can be determined from a top of the first level of interconnect wiring 104). The first portion 108 of the plurality of metal conductive lines 106 can be electrically connected with one or more capacitively optimized devices; and the second portion 110 of the plurality of metal conductive lines 106 can be electrically connected with one or more resistively optimized devices.

With embodiments, the semiconductor device 100 can include a second level of interconnect wiring 112 having a second plurality of metal conductive lines 114. The second level of interconnect wiring 112 can be disposed vertically above the first level of interconnect wiring 104 (e.g., can be disposed adjacent in the z-direction). The first level of interconnect wiring 104 can be in electrical communication with the second level of interconnect wiring 112. In examples, the second plurality of metal conductive lines 114 can include a first portion 116 and a second portion 118. The first portion 116 of the second plurality of metal conductive lines 114 can include a first height 116H, and the second portion 118 of the second plurality of metal conductive lines 114 can include a second height 118H. In examples, the first height 116H and the second height 118H can be substantially the same heights or substantially different heights. The heights of the second plurality of metal conductive lines 114 can include variable heights such as to optimize resistive and/or capacitive properties of the semiconductor device 100 and/or devices/components connected thereto.

In embodiments, the semiconductor device 100 can include a plurality of vias including a first via 120 and a second via 122. In examples, the semiconductor device 100 can include any number of vias to connect various layers of the semiconductor device 100. The first via 120 and the second via 122 can be formed via a damascene process, which can result in the first via 120 and the second via 122 having a damascene profile (e.g., where a width at a bottom of the via is smaller than a width at a top of the via). The first via 120 and the second via 122 can facilitate an electrical connection between the first level of interconnect wiring 104 and the second level of interconnect wiring 112. Further, the first via 120 and the second via 122 can be disposed vertically (e.g., in the z-direction) between the first level of interconnect wiring 104 and the second level of interconnect wiring 112.

Such as illustrated by FIG. 1, the plurality of vias can include variable heights for optimized circuit performance (e.g., resistance and capacitance). The first via 120 and the second via 122 can include different heights. The heights of the first via 120 and the second via 122 can differ by more than a fabrication variance for the semiconductor device 100 (and the components connected therewith). The first via 120 can include a first height 120H and the second via 122 can include a second height 122H. The second height can be about 25% greater than the first height 120H (e.g., which can account for fabrication variances of the semiconductor device 100). With embodiments, the first height 120H can be measured from a top of the second level of interconnect wiring 112 (e.g., or the bottom of the first level of interconnect wiring 104).

Additionally, the semiconductor device 100 can include an adhesion layer 130 and/or an interlayer dielectric 132. In some portions of the semiconductor device 100 (such as illustrated in FIG. 1), the adhesion layer 130 and the interlayer dielectric 134 can be disposed between the first level of interconnect wiring 104 and the second level of interconnect wiring 112. The adhesion layer 130 can include any variety of adhesive and/or insulative materials to isolate the connections between the first level of interconnect wiring 104 and the second level of interconnect wiring 112 with the interlayer dielectric 132. Further, the adhesion layer 130 can include an insulating or dielectric material positioned between conductive portions of a via structure, line structure, and/or substrate such that an electronic signal, a ground, a supply voltage, carried by such a via structure can be prevented from leaking into the substrate which can cause shorting, signal loss, attenuation, or other circuit failure.

In embodiments, such as generally illustrated by FIG. 2, the plurality of metal conductive lines 206 of the first level of interconnect wiring 204 can include similar heights (e.g., about the same heights). Repetitive description of like elements employed in other embodiments described herein is omitted for sake of brevity. For example, the height 206H of the plurality of metal conductive lines 206 can be the same throughout portions of the semiconductor device 100.

For example and without limitation, the second level of interconnect wiring 212 including the second plurality of metal conductive lines 214 can be electrically connected with the first level of interconnect wiring 204 by the first via 220 and the second via 222. Further, the first portion 116 and the second portion 118 of the second plurality of metal conductive lines can include different heights (e.g., first height 216H of first portion 216 and second height 218H of second portion 218) that can be determined from a top of the second level of interconnect wiring 212. The first portion 216 and the second portion 218 can be disposed substantially proximate each other in the x-direction). The difference between the first height 216H of the first portion 216 and the second height 218H of the second portion 218 can be at least about 25% (e.g., or an amount that is greater than the fabrication variance for the semiconductor device 100 and related components/elements). The second level of interconnect wiring 212 can include variable heights such as to provide a manner of RC optimization for connected components to the first level of interconnect wiring 204 and the second level of interconnect wiring 212.

With embodiments, the first via 220 and the second via 222 can have differing heights (e.g., in response to the second level of interconnect wiring 212 having variable heights). The first height 220H of the first via 220 can be greater than the second height 222H of the second via 222 (e.g., by about 25% or an amount that is at least greater than a fabrication variance for the semiconductor device 100). The first via 220 and the second via 222 can be formed via a damascene process, resulting in a damascene profile for the second plurality of metal conductive lines 214. In a similar manner to the embodiment shown in FIG. 1 (e.g., as indicated by adhesion layer 130), the semiconductor device 100 can include an adhesion layer 230 disposed on the surface of the plurality of metal conductive lines 206 to isolate connections between the first level of interconnect wiring 204 and the second level of interconnect wiring 212 from contacting the interlayer dielectric 232.

Turning now to FIG. 3, the first level of interconnect wiring 104 can be connected with one or more components (e.g., logic gates, inverters, etc.). For example and without limitation, the one or more components can include a first inverter 300, a second inverter 302, and a third inverter 304. The first inverter 300 and the second inverter 302 can be small inverters (e.g., an INV×1 inverter that can span a single poly pitch). The first inverter 300 and the second inverter 302 can be capacitance sensitive. Further, the first level of interconnect wiring 104 can include a variable height along the plurality of metal conductive lines 106 to optimize connections to the first inverter 300, the second inverter 302, and the third inverter 304. A first portion 300′ and a second portion 302′ of the plurality of metal conductive lines 106 of the first level of interconnect wiring 104 can include a lesser height to optimize connections with respect to capacitance to the first inverter 300 and the second inverter 302. The first inverter 300 and the second inverter 302 can be sensitive to capacitance; thus, the heights of the plurality of metal conductive lines 106 can be shorter (e.g., smaller) to provide a lower capacitive connection within the semiconductor device 100. In other words, conductive lines having a shorter height can include lesser capacitance properties and greater resistance properties (e.g., a liner relation of the height of the line with respect to changing resistance or capacitance values). Conversely, conductive lines having a greater height can include greater capacitance properties and lesser resistance properties (e.g., in the case of connecting the third inverter 304).

With embodiments, the third inverter 304 can be a relatively large inverter (e.g., an INV×20 inverter that can span 20 poly pitches). The third inverter 304 can be sensitive to resistance, thus, the heights of the plurality of metal conductive lines 106 can be shorter to provide a lower resistance connection within the semiconductor device 100. A third portion 304′ of the plurality of metal conductive lines 106 can include a greater height to optimize connections with respect to resistance along the first level of interconnect wiring 104. Heights of the first level of interconnect wiring 104 and the second level of interconnect wiring 112 can be tuned depending on the logic gate or inverter connected therewith.

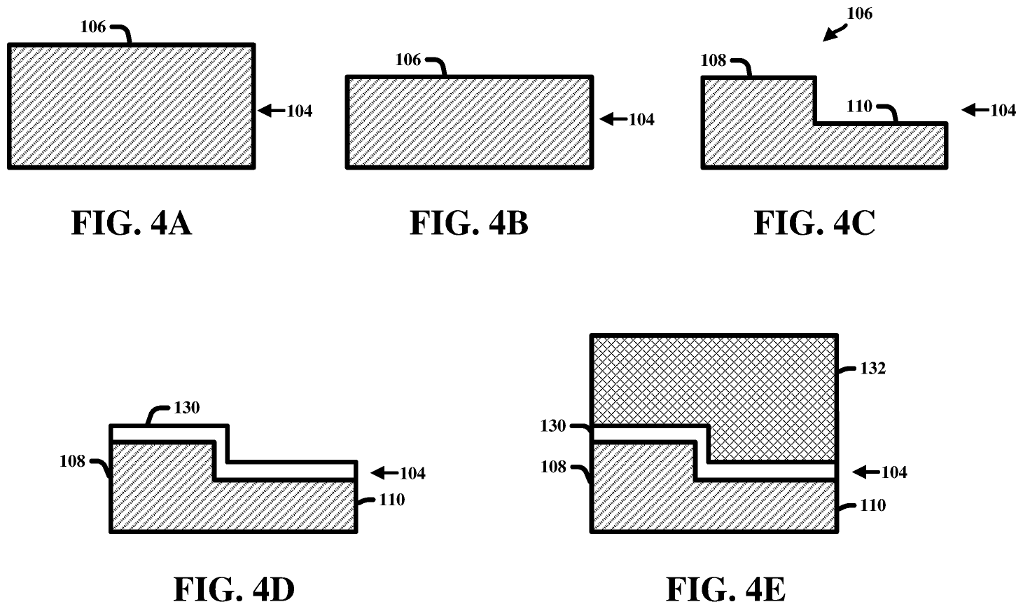

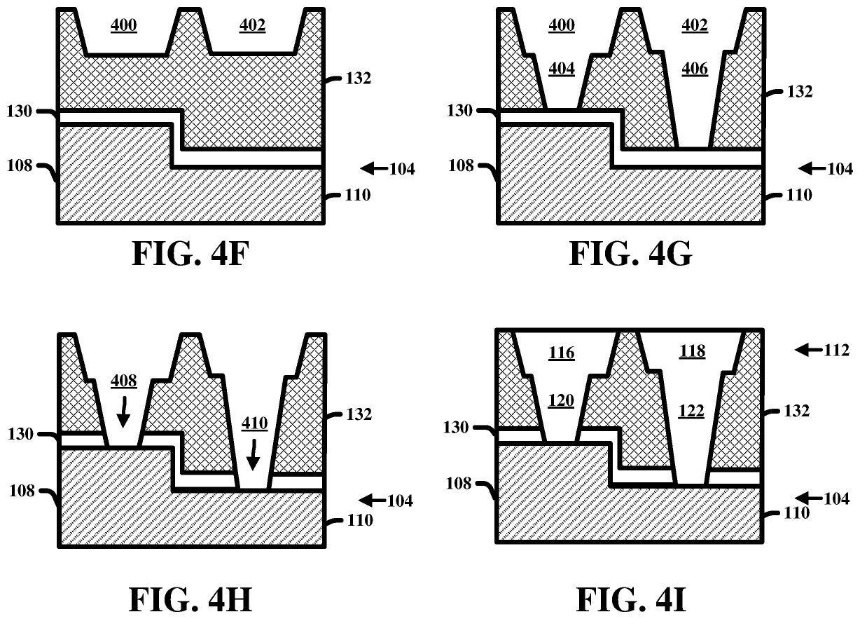

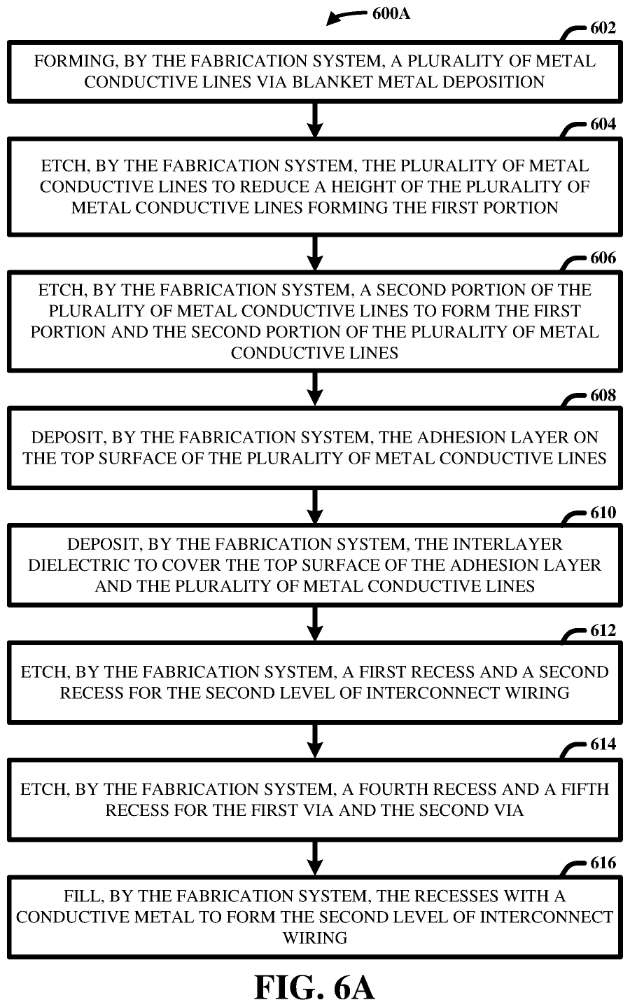

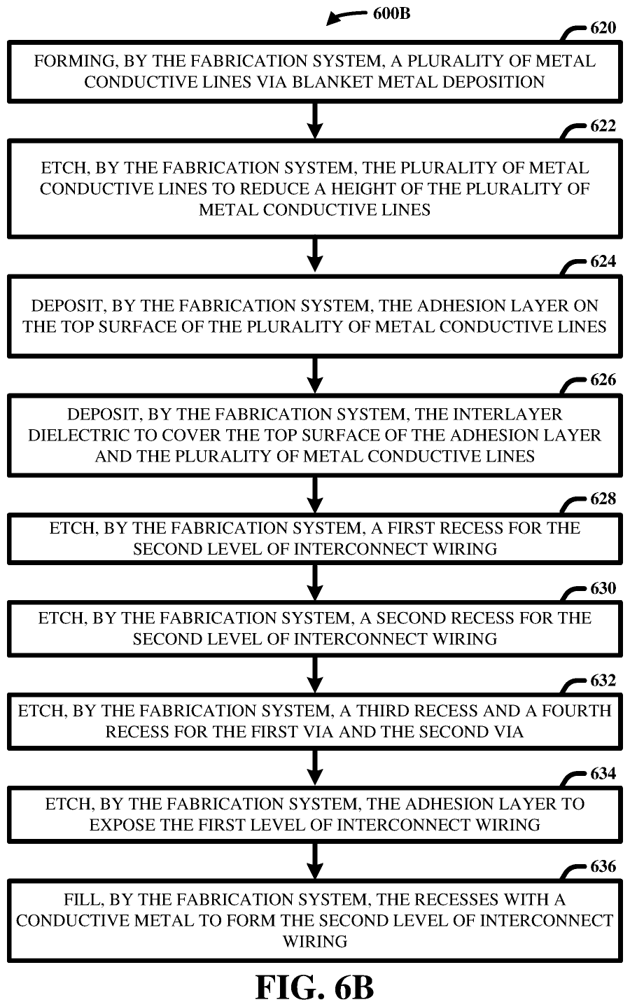

In embodiments, FIGS. 4A-4I and FIG. 6A illustrate a method 600A of fabricating the semiconductor device 100 by a fabrication system such that the first level of interconnect wiring 104 includes variable heights. The plurality of metal conductive lines 106 can be formed via a blanket metal deposition, as indicated by FIG. 4A (step 602). The fabrication system can perform a first metal etch to reduce a height of the plurality of metal conductive lines 106, as illustrated in FIG. 4B (step 604). The first metal etch can determine the first height 108H of the first portion 108 of the plurality of metal conductive lines 106. The fabrication system can perform a second metal etch on a second portion 110 to further reduce a height of the plurality of metal conductive lines 106, as shown in FIG. 4C (step 606). The second metal etch can determine the second height 110H of the second portion 110 of the plurality of metal conductive lines 106. The first portion 108 and the second portion 110 can be formed by a subtractive process resulting in a subtractive profile of the plurality of metal conductive lines 106.

With embodiments, as shown in FIG. 4D, the fabrication system can deposit the adhesion layer 130 on the top surface of the plurality of metal conductive lines 106 (step 608). The adhesion layer 130 can include an adhesion dielectric material such that subsequent dielectric layers will stick (e.g., remain substantially fixed in the x, y, and z-directions with the first level of interconnect wiring 104). The fabrication system can deposit the interlayer dielectric 132 on the top surface of the adhesion layer 130, as shown in FIG. 4E (step 610). For example, the interlayer dielectric 132 can cover the adhesion layer 130 such that the top surface of the adhesion layer 130 is not exposed. Further, as illustrated by FIG. 4F, the fabrication system can perform a line etch to create a first recess 400 and a second recess 402 for the second level of interconnect wiring 112 (via a damascene patterning process) (step 612). Portions of the interlayer dielectric 132 can be removed (e.g., via lithography or etching) to facilitate electrical connection between the first level of interconnect wiring 104 and the second level of interconnect wiring 112.

In embodiments, such as illustrated in FIG. 4G, the fabrication system can further etch the interlayer dielectric 132 to form a third recess 404 and a fourth recess 406 for the first via 120 and the second via 122 in the same etch step (step 614). The first via 120 and the second via 122 can include heights 120H, 122H that correlate to the heights 108H, 110H of the first portion 108 and the second portion 110. Taller/greater heights of the first portion 108 can result in shorter/lesser heights for the first via 120. Similarly, shorter/lesser heights of the second portion 110 can result in taller/greater heights of the second via 122. In examples, different via heights can be facilitated with the single etching step of FIG. 4G due to the varying heights of the first portion 108 and the second portion 110 of the plurality of metal conductive lines of the first level of interconnect wiring 104. The fabrication system can etch the third recess 404 and the fourth recess 406 through the interlayer dielectric 132 until reaching the adhesion layer 130 (e.g., illustrated by fifth recess 408 and sixth recess 410). Further, as shown in FIG. 4H, the adhesion layer 130 can be etched away by removing the hard mask of the adhesion layer 130 exposing the top surfaces of the plurality of metal conductive lines 106 of the first level of interconnect wiring 104.

With embodiments, such as shown in FIG. 4I, the fabrication system can additionally fill the first recess 400, the second recess 402, the third recess 404, the fourth recess 406, the fifth recess 408, and the sixth recess 410 with a conductive metal thus forming the second level of interconnect wiring 112 having the first portion 116 and the second portion 118, the first via 120, and the second via 122 (step 616).

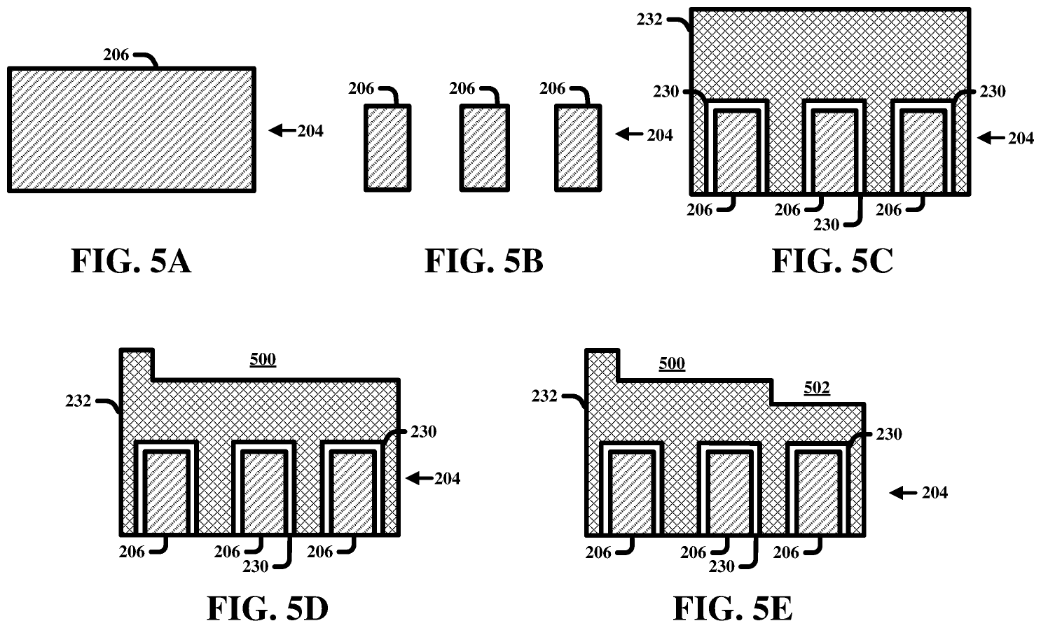

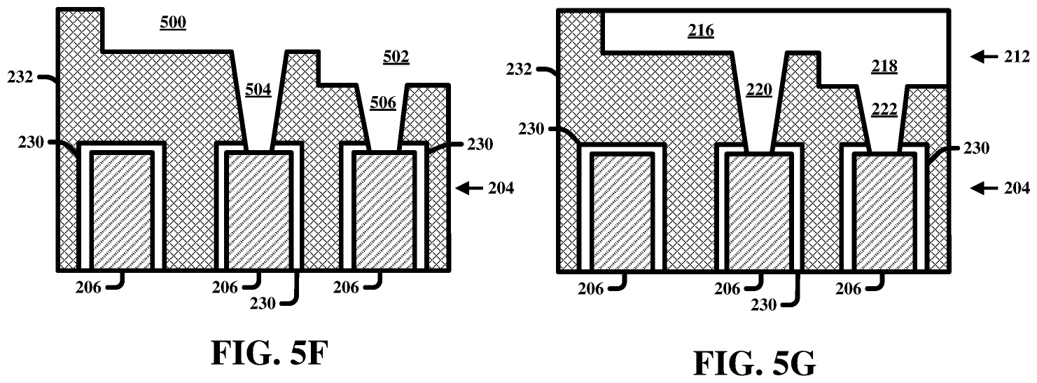

In embodiments, FIGS. 5A-5G and FIG. 6B illustrate a method 600B of fabricating the semiconductor device 100 by a fabrication system such that the second level of interconnect wiring 212 includes variable heights. The plurality of metal conductive lines 206 can be formed via a blanket metal deposition, as indicated by FIG. 5A (step 620). The fabrication system can perform a metal etch to reduce a height of the plurality of metal conductive lines 206, as illustrated in FIG. 5B (e.g., via a subtractive process resulting in subtractive patterning of the first level of interconnect wiring 204) (step 622). The metal etch can determine the height 206H of the plurality of metal conductive lines 206 (e.g., where the plurality of metal conductive lines 206 include substantially the same height). An adhesion layer can be deposited on the outer surfaces of the plurality of metal conductive lines to facilitate adhesion between the first layer of interconnect wiring 202 and the interlayer dielectric 232 (e.g., in a similar manner to the adhesion layer 130 depicted in FIG. 4D) (step 624). The adhesion layer can include an adhesion dielectric material such that subsequent dielectric layers will stick (e.g., remain substantially fixed in the x, y, and z-directions with the first level of interconnect wiring 204).

With embodiments, the fabrication system can deposit the interlayer dielectric 232 on the top surface of the adhesion layer covering the plurality of metal conductive lines 206, as shown in FIG. 5C (step 626). For example, the interlayer dielectric 232 can cover the adhesion layer (covering the plurality of metal conductive lines 206) such that the top surface of the adhesion layer is not exposed.

Further, as illustrated by FIG. 5D, the fabrication system can perform a first line etch to create a first recess 500 for the first portion 216 of the second plurality of metal conductive lines 214 of the second level of interconnect wiring 212 (via a damascene patterning process) (step 628). The first line etch can determine the first height 216H of the first portion 216 of the second plurality of metal conductive lines 214. Portions of the interlayer dielectric 232 can be removed (e.g., via lithography or etching) to facilitate electrical connection between the first level of interconnect wiring 202 and the second level of interconnect wiring 212. A second line etch, as shown by FIG. 5E can create a second recess 502 for the second portion 218 of the second plurality of metal conductive lines 214 (step 630). The second line etch can determine the height 218H of the second portion 218 of the second plurality of metal conductive lines 214.

In embodiments, such as illustrated in FIG. 5F, the fabrication system can further etch the interlayer dielectric 232 to form a third recess 504 and a fourth recess 506 for the first via 220 and the second via 222 in the same etch step (step 632). The first via 220 and the second via 222 can include heights 220H, 222H that correlate to the heights 216H, 218H of the first portion 216 and the second portion 218 of the second plurality of metal conductive lines 214. Shorter/lesser heights, like first height 216H, of the first portion 216 can result in taller/greater heights 220H for the first via 220. Similarly, taller/greater heights of the second portion 218 can result in shorter/lesser heights of the second via 222 (e.g., due to the top of the second level of interconnect wiring being fixed in the Z-direction).

With examples, the fabrication system can etch the third recess 504 and the fourth recess 506 through the interlayer dielectric 232 until reaching the adhesion layer. Further, the adhesion layer can be etched away by removing the hard mask of the adhesion layer exposing the top surfaces of the plurality of metal conductive lines 206 of the first level of interconnect wiring 204 (step 634). As demonstrated in FIG. 5G, the fabrication system can additionally fill the first recess 500, the second recess 502, the third recess 504, and the fourth recess 406 with a conductive metal thus forming the second level of interconnect wiring 212 having the first portion 216 and the second portion 218, the first via 220, and the second via 222 (step 636).

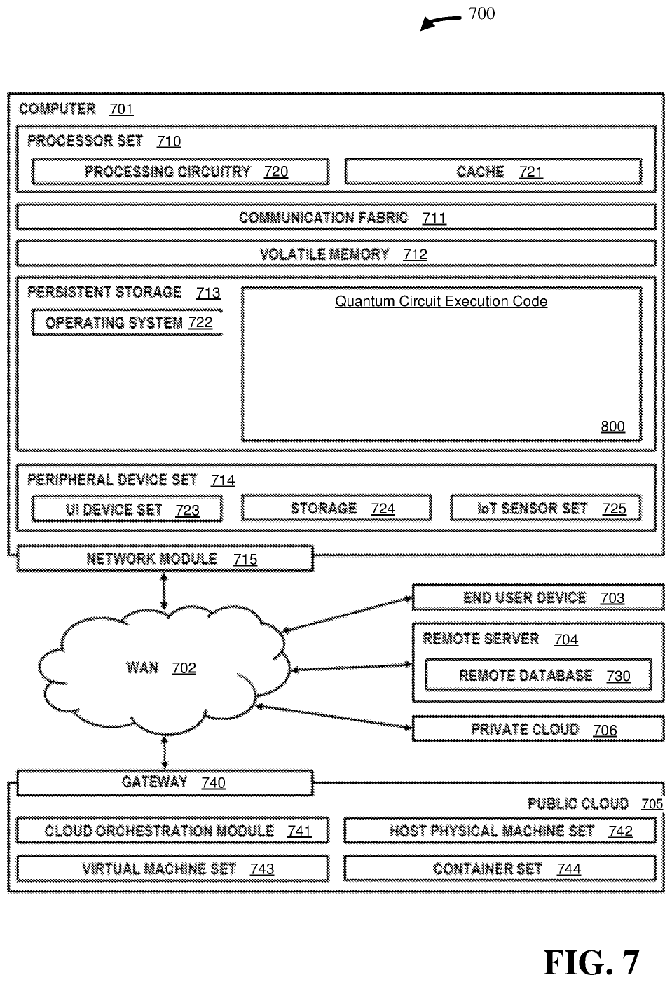

For example, one or more embodiments described herein of the semiconductor device 100 and/or one or more components thereof can employ one or more computing resources of the computing environment 700 described below with reference to the illustration 700 of FIG. 7. For instance, the system and/or components thereof can employ one or more classical and/or quantum computing resources to execute one or more classical and/or quantum: mathematical functions, calculations and/or equations; computing and/or processing scripts; algorithms; models (e.g., artificial intelligence (AI) models, machine learning (ML) models and/or like model); and/or another operation in accordance with one or more embodiments described herein.

It is to be understood that although one or more embodiments described herein include a detailed description on cloud computing, implementation of the teachings recited herein are not limited to a cloud computing environment. Rather, one or more embodiments described herein are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines and services) that can be rapidly provisioned and released with minimal management effort or interaction with a provider of the service. This cloud model can include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but can be able to specify location at a higher level of abstraction (e.g., country, state or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth and active user accounts). Resource usage can be monitored, controlled and reported, providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage or individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems or storage, but has control over the deployed applications and possibly application hosting environment configurations.

Infrastructure as a Service (IaaS): the capability provided to the consumer is to provision processing, storage, networks and/or other fundamental computing resources where the consumer can deploy and run arbitrary software, which can include operating systems and applications. The consumer does not manage or control the underlying cloud infrastructure but has control over operating systems, storage, deployed applications and/or possibly limited control of select networking components (e.g., host firewalls).

A cloud computing environment is service oriented with a focus on statelessness, low coupling, modularity and/or semantic interoperability. At the heart of cloud computing is an infrastructure that includes a network of interconnected nodes.

FIG. 7 and the following discussion are intended to provide a general description of a suitable computing environment 700 in which one or more embodiments described herein at FIGS. 1-6B can be implemented. For example, various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks can be performed in reverse order, as a single integrated step, concurrently or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium can be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 700 contains an example of an environment for the execution of at least some of the computer code involved in performing the inventive methods, such as translation of an original source code based on a configuration of a target system by the quantum circuit execution code 800. In addition to block 800, computing environment 700 includes, for example, computer 701, wide area network (WAN) 702, end user device (EUD) 703, remote server 704, public cloud 705, and private cloud 706. In this embodiment, computer 701 includes processor set 710 (including processing circuitry 720 and cache 721), communication fabric 711, volatile memory 712, persistent storage 713 (including operating system 722 and block 800, as identified above), peripheral device set 714 (including user interface (UI), device set 723, storage 724, and Internet of Things (IoT) sensor set 725), and network module 715. Remote server 704 includes remote database 730. Public cloud 705 includes gateway 740, cloud orchestration module 741, host physical machine set 742, virtual machine set 743, and container set 744.

COMPUTER 701 can take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 730. As is well understood in the art of computer technology, and depending upon the technology, performance of a computer-implemented method can be distributed among multiple computers and/or between multiple locations. On the other hand, in this presentation of computing environment 700, detailed discussion is focused on a single computer, specifically computer 701, to keep the presentation as simple as possible. Computer 701 can be located in a cloud, even though it is not shown in a cloud in FIG. 7. On the other hand, computer 701 is not required to be in a cloud except to any extent as can be affirmatively indicated.

PROCESSOR SET 710 includes one, or more, computer processors of any type now known or to be developed in the future. Processing circuitry 720 can be distributed over multiple packages, for example, multiple, coordinated integrated circuit chips. Processing circuitry 720 can implement multiple processor threads and/or multiple processor cores. Cache 721 is memory that is located in the processor chip package(s) and is typically used for data or code that should be available for rapid access by the threads or cores running on processor set 710. Cache memories are typically organized into multiple levels depending upon relative proximity to the processing circuitry. Alternatively, some, or all, of the cache for the processor set can be located “off chip.” In some computing environments, processor set 710 can be designed for working with qubits and performing quantum computing.

Computer readable program instructions are typically loaded onto computer 701 to cause a series of operational steps to be performed by processor set 710 of computer 701 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 721 and the other storage media discussed below. The program instructions, and associated data, are accessed by processor set 710 to control and direct performance of the inventive methods. In computing environment 700, at least some of the instructions for performing the inventive methods can be stored in block 800 in persistent storage 713.

COMMUNICATION FABRIC 711 is the signal conduction path that allows the various components of computer 701 to communicate with each other. Typically, this fabric is made of switches and electrically conductive paths, such as the switches and electrically conductive paths that make up busses, bridges, physical input/output ports and the like. Other types of signal communication paths can be used, such as fiber optic communication paths and/or wireless communication paths.

VOLATILE MEMORY 712 is any type of volatile memory now known or to be developed in the future. Examples include dynamic type random access memory (RAM) or static type RAM. Typically, the volatile memory is characterized by random access, but this is not required unless affirmatively indicated. In computer 701, the volatile memory 712 is located in a single package and is internal to computer 701, but, alternatively or additionally, the volatile memory can be distributed over multiple packages and/or located externally with respect to computer 701.

PERSISTENT STORAGE 713 is any form of non-volatile storage for computers that is now known or to be developed in the future. The non-volatility of this storage means that the stored data is maintained regardless of whether power is being supplied to computer 701 and/or directly to persistent storage 713. Persistent storage 713 can be a read only memory (ROM), but typically at least a portion of the persistent storage allows writing of data, deletion of data and re-writing of data. Some familiar forms of persistent storage include magnetic disks and solid-state storage devices. Operating system 722 can take several forms, such as various known proprietary operating systems or open-source Portable Operating System Interface type operating systems that employ a kernel. The code included in block 800 typically includes at least some of the computer code involved in performing the inventive methods.

PERIPHERAL DEVICE SET 714 includes the set of peripheral devices of computer 701. Data communication connections between the peripheral devices and the other components of computer 701 can be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 723 can include components such as a display screen, speaker, microphone, wearable devices (such as goggles and smart watches), keyboard, mouse, printer, touchpad, game controllers, and haptic devices. Storage 724 is external storage, such as an external hard drive, or insertable storage, such as an SD card. Storage 724 can be persistent and/or volatile. In some embodiments, storage 724 can take the form of a quantum computing storage device for storing data in the form of qubits. In embodiments where computer 701 is required to have a large amount of storage (for example, where computer 701 locally stores and manages a large database) then this storage can be provided by peripheral storage devices designed for storing large amounts of data, such as a storage area network (SAN) that is shared by multiple, geographically distributed computers. IoT sensor set 725 is made up of sensors that can be used in Internet of Things applications. For example, one sensor can be a thermometer and another sensor can be a motion detector.

NETWORK MODULE 715 is the collection of computer software, hardware, and firmware that allows computer 701 to communicate with other computers through WAN 702. Network module 715 can include hardware, such as modems or Wi-Fi signal transceivers, software for packetizing and/or de-packetizing data for communication network transmission, and/or web browser software for communicating data over the internet. In some embodiments, network control functions and network forwarding functions of network module 715 are performed on the same physical hardware device. In other embodiments (for example, embodiments that utilize software-defined networking (SDN)), the control functions and the forwarding functions of network module 715 are performed on physically separate devices, such that the control functions manage several different network hardware devices. Computer readable program instructions for performing the inventive methods can typically be downloaded to computer 701 from an external computer or external storage device through a network adapter card or network interface included in network module 715.

WAN 702 is any wide area network (for example, the internet) capable of communicating computer data over non-local distances by any technology for communicating computer data, now known or to be developed in the future. In some embodiments, the WAN can be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 703 is any computer system that is used and controlled by an end user (for example, a customer of an enterprise that operates computer 701) and can take any of the forms discussed above in connection with computer 701. EUD 703 typically receives helpful and useful data from the operations of computer 701. For example, in a hypothetical case where computer 701 is designed to provide a recommendation to an end user, this recommendation would typically be communicated from network module 715 of computer 701 through WAN 702 to EUD 703. In this way, EUD 703 can display, or otherwise present, the recommendation to an end user. In some embodiments, EUD 703 can be a client device, such as thin client, heavy client, mainframe computer and/or desktop computer.

REMOTE SERVER 704 is any computer system that serves at least some data and/or functionality to computer 701. Remote server 704 can be controlled and used by the same entity that operates computer 701. Remote server 704 represents the machine(s) that collect and store helpful and useful data for use by other computers, such as computer 701. For example, in a hypothetical case where computer 701 is designed and programmed to provide a recommendation based on historical data, then this historical data can be provided to computer 701 from remote database 730 of remote server 704.

PUBLIC CLOUD 705 is any computer system available for use by multiple entities that provides on-demand availability of computer system resources and/or other computer capabilities, especially data storage (cloud storage) and computing power, without direct active management by the scale. The direct and active management of the computing resources of public cloud 705 is performed by the computer hardware and/or software of cloud orchestration module 741. The computing resources provided by public cloud 705 are typically implemented by virtual computing environments that run on various computers making up the computers of host physical machine set 742, which is the universe of physical computers in and/or available to public cloud 705. The virtual computing environments (VCEs) typically take the form of virtual machines from virtual machine set 743 and/or containers from container set 744. It is understood that these VCEs can be stored as images and can be transferred among and between the various physical machine hosts, either as images or after instantiation of the VCE. Cloud orchestration module 741 manages the transfer and storage of images, deploys new instantiations of VCEs and manages active instantiations of VCE deployments. Gateway 740 is the collection of computer software, hardware and firmware allowing public cloud 705 to communicate through WAN 702.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 706 is similar to public cloud 705, except that the computing resources are only available for use by a single enterprise. While private cloud 706 is depicted as being in communication with WAN 702, in other embodiments a private cloud can be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 705 and private cloud 706 are both part of a larger hybrid cloud.

The embodiments described herein can be directed to one or more of a system, a method, an apparatus and/or a computer program product at any possible technical detail level of integration. The computer program product can include a computer readable storage medium (or media) having computer readable program instructions thereon for causing a processor to carry out aspects of the one or more embodiments described herein. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a superconducting storage device and/or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon and/or any suitable combination of the foregoing. A computer readable storage medium, as used herein, is not to be construed as being transitory signals per se, such as radio waves and/or other freely propagating electromagnetic waves, electromagnetic waves propagating through a waveguide and/or other transmission media (e.g., light pulses passing through a fiber-optic cable), and/or electrical signals transmitted through a wire.

Computer readable program instructions described herein can be downloaded to respective computing/processing devices from a computer readable storage medium and/or to an external computer or external storage device via a network, for example, the Internet, a local area network, a wide area network and/or a wireless network. The network can comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of the one or more embodiments described herein can be assembler instructions, instruction-set-architecture (ISA) instructions, machine instructions, machine dependent instructions, microcode, firmware instructions, state-setting data, configuration data for integrated circuitry, and/or source code and/or object code written in any combination of one or more programming languages, including an object oriented programming language such as Smalltalk, C++ or the like, and/or procedural programming languages, such as the “C” programming language and/or similar programming languages. The computer readable program instructions can execute entirely on a computer, partly on a computer, as a stand-alone software package, partly on a computer and/or partly on a remote computer or entirely on the remote computer and/or server. In the latter scenario, the remote computer can be connected to a computer through any type of network, including a local area network (LAN) and/or a wide area network (WAN), and/or the connection can be made to an external computer (for example, through the Internet using an Internet Service Provider). In one or more embodiments, electronic circuitry including, for example, programmable logic circuitry, field-programmable gate arrays (FPGA) and/or programmable logic arrays (PLA) can execute the computer readable program instructions by utilizing state information of the computer readable program instructions to personalize the electronic circuitry, in order to perform aspects of the one or more embodiments described herein.

Aspects of the one or more embodiments described herein are described with reference to flowchart illustrations and/or block diagrams of methods, apparatus (systems), and computer program products according to one or more embodiments described herein. It will be understood that each block of the flowchart illustrations and/or block diagrams, and combinations of blocks in the flowchart illustrations and/or block diagrams, can be implemented by computer readable program instructions. These computer readable program instructions can be provided to a processor of a general-purpose computer, special purpose computer and/or other programmable data processing apparatus to produce a machine, such that the instructions, which execute via the processor of the computer or other programmable data processing apparatus, can create means for implementing the functions/acts specified in the flowchart and/or block diagram block or blocks. These computer readable program instructions can also be stored in a computer readable storage medium that can direct a computer, a programmable data processing apparatus and/or other devices to function in a particular manner, such that the computer readable storage medium having instructions stored therein can comprise an article of manufacture including instructions which can implement aspects of the function/act specified in the flowchart and/or block diagram block or blocks. The computer readable program instructions can also be loaded onto a computer, other programmable data processing apparatus and/or other device to cause a series of operational acts to be performed on the computer, other programmable apparatus and/or other device to produce a computer implemented process, such that the instructions which execute on the computer, other programmable apparatus and/or other device implement the functions/acts specified in the flowchart and/or block diagram block or blocks.

The flowcharts and block diagrams in the figures illustrate the architecture, functionality and/or operation of possible implementations of systems, computer-implementable methods and/or computer program products according to one or more embodiments described herein. In this regard, each block in the flowchart or block diagrams can represent a module, segment and/or portion of instructions, which comprises one or more executable instructions for implementing the specified logical function. In one or more alternative implementations, the functions noted in the blocks can occur out of the order noted in the Figures. For example, two blocks shown in succession can be executed substantially concurrently, and/or the blocks can sometimes be executed in the reverse order, depending upon the functionality involved. It will also be noted that each block of the block diagrams and/or flowchart illustration, and/or combinations of blocks in the block diagrams and/or flowchart illustration, can be implemented by special purpose hardware-based systems that can perform the specified functions and/or acts and/or carry out one or more combinations of special purpose hardware and/or computer instructions.

While the subject matter has been described above in the general context of computer-executable instructions of a computer program product that runs on a computer and/or computers, those skilled in the art will recognize that the one or more embodiments herein also can be implemented at least partially in parallel with one or more other program modules. Generally, program modules include routines, programs, components and/or data structures that perform particular tasks and/or implement particular abstract data types. Moreover, the aforedescribed computer-implemented methods can be practiced with other computer system configurations, including single-processor and/or multiprocessor computer systems, mini-computing devices, mainframe computers, as well as computers, hand-held computing devices (e.g., PDA, phone), and/or microprocessor-based or programmable consumer and/or industrial electronics. The illustrated aspects can also be practiced in distributed computing environments in which tasks are performed by remote processing devices that are linked through a communications network. However, one or more, if not all aspects of the one or more embodiments described herein can be practiced on stand-alone computers. In a distributed computing environment, program modules can be located in both local and remote memory storage devices.

As used in this application, the terms “component,” “system,” “platform” and/or “interface” can refer to and/or can include a computer-related entity or an entity related to an operational machine with one or more specific functionalities. The entities described herein can be either hardware, a combination of hardware and software, software, or software in execution. For example, a component can be, but is not limited to being, a process running on a processor, a processor, an object, an executable, a thread of execution, a program and/or a computer. By way of illustration, both an application running on a server and the server can be a component. One or more components can reside within a process and/or thread of execution and a component can be localized on one computer and/or distributed between two or more computers. In another example, respective components can execute from various computer readable media having various data structures stored thereon. The components can communicate via local and/or remote processes such as in accordance with a signal having one or more data packets (e.g., data from one component interacting with another component in a local system, distributed system and/or across a network such as the Internet with other systems via the signal). As another example, a component can be an apparatus with specific functionality provided by mechanical parts operated by electric or electronic circuitry, which is operated by a software and/or firmware application executed by a processor. In such a case, the processor can be internal and/or external to the apparatus and can execute at least a part of the software and/or firmware application. As yet another example, a component can be an apparatus that provides specific functionality through electronic components without mechanical parts, where the electronic components can include a processor and/or other means to execute software and/or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter described herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

As it is employed in the subject specification, the term “processor” can refer to substantially any computing processing unit and/or device comprising, but not limited to, single-core processors; single-processors with software multithread execution capability; multi-core processors; multi-core processors with software multithread execution capability; multi-core processors with hardware multithread technology; parallel platforms; and/or parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, and/or any combination thereof designed to perform the functions described herein. Further, processors can exploit nano-scale architectures such as, but not limited to, molecular and quantum-dot based transistors, switches and/or gates, in order to optimize space usage and/or to enhance performance of related equipment. A processor can be implemented as a combination of computing processing units.

Herein, terms such as “store,” “storage,” “data store,” data storage,” “database,” and substantially any other information storage component relevant to operation and functionality of a component are utilized to refer to “memory components,” entities embodied in a “memory,” or components comprising a memory. Memory and/or memory components described herein can be either volatile memory or nonvolatile memory or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory and/or nonvolatile random-access memory (RAM) (e.g., ferroelectric RAM (FeRAM). Volatile memory can include RAM, which can act as external cache memory, for example. By way of illustration and not limitation, RAM can be available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM) and/or Rambus dynamic RAM (RDRAM). Additionally, the described memory components of systems and/or computer-implemented methods herein are intended to include, without being limited to including, these and/or any other suitable types of memory.

What has been described above includes mere examples of systems and computer-implemented methods. It is, of course, not possible to describe every conceivable combination of components and/or computer-implemented methods for purposes of describing the one or more embodiments, but one of ordinary skill in the art can recognize that many further combinations and/or permutations of the one or more embodiments are possible. Furthermore, to the extent that the terms “includes,” “has,” “possesses,” and the like are used in the detailed description, claims, appendices and/or drawings such terms are intended to be inclusive in a manner similar to the term “comprising” as “comprising” is interpreted when employed as a transitional word in a claim.

The descriptions of the various embodiments have been presented for purposes of illustration but are not intended to be exhaustive or limited to the embodiments described herein. Many modifications and variations will be apparent to those of ordinary skill in the art without departing from the scope and spirit of the described embodiments. The terminology used herein was chosen to best explain the principles of the embodiments, the practical application and/or technical improvement over technologies found in the marketplace, and/or to enable others of ordinary skill in the art to understand the embodiments described herein.

What is claimed is:

1. A semiconductor device comprising:
a substrate;
a first level of interconnect wiring including a plurality of metal conductive lines electrically coupled to the substrate;
a first portion of the plurality of metal conductive lines including a first height; and
a second portion of the plurality of metal conductive lines including a second height;
wherein the second height is greater than the first height.

2. The semiconductor device of claim 1, wherein the first height and the second height are optimized for at least one of resistance or capacitance for electrical connections with the first level of interconnect wiring.

3. The semiconductor device of claim 1, wherein the second height is different from the first height by at least about 25%.

4. The semiconductor device of claim 3, wherein the first height and the second height are determined from a top of the first level of interconnect wiring.

5. The semiconductor device of claim 3, wherein the first height and the second height are determined from a bottom of the first level of interconnect wiring.

6. The semiconductor device of claim 5, wherein a bottom of the plurality of metal conductive lines is fixed in a z-direction.

7. The semiconductor device of claim 2, wherein the plurality of metal conductive lines include a subtractive profile.

8. The semiconductor device of claim 1, further comprising:
a second level of interconnect wiring disposed vertically above the first level of interconnect wiring including a second plurality of metal conductive lines;
a plurality of vias connecting the first level of interconnect wiring to the second level of interconnect wiring;
wherein a top of the plurality of vias are fixed in a z-direction.

9. The semiconductor device of claim 8, wherein the plurality of vias include a damascene profile.

10. The semiconductor device of claim 9, wherein the plurality of vias include a first group of vias having a first height; a second group of vias having a second height; and the first height of the first group of vias is greater than the second height of the second group of vias.

11. A semiconductor device comprising:
a substrate;
a first level of interconnect wiring including a plurality of metal conductive lines electrically coupled to the substrate; and
a second level of interconnect wiring including a second plurality of metal conductive lines having a first portion and a second portion; and
a plurality of vias connecting the first level of interconnect wiring to the second level of interconnect wiring;
wherein at least one of the first level of interconnect wiring and the second level of interconnect wiring includes a variable height and the plurality of vias include variable heights.

12. The semiconductor device of claim 11, wherein the variable height is optimized for at least one of resistance or capacitance for electrical connections with the first level of interconnect wiring and the second level of interconnect wiring.

13. The semiconductor device of claim 12, wherein the plurality of metal conductive lines electrically coupled to the substrate include a subtractive profile.

14. The semiconductor device of claim 13, wherein the plurality of vias include a damascene profile.

15. The semiconductor device of claim 14, wherein the plurality of vias include a first group and a second group; the first group of the plurality of vias includes a first height; the second group of the plurality of vias includes a second height; and the second height of the second group is greater than the first height of the first group by at least 25%.

16. A method for fabricating a semiconductor device by a fabrication system, the method comprising:
providing, by the fabrication system, a substrate; a first level of interconnect wiring including a first plurality of metal conductive lines electrically coupled to the substrate; and a second level of interconnect wiring including a second plurality of metal conductive lines electrically coupled to the substrate;
etching, by the fabrication system, a first portion of at least one of the first plurality of metal conductive lines and the second plurality of metal conductive lines to include a first height;
etching, by the fabrication system, a second portion of the at least one of the first plurality of metal conductive lines and the second plurality of metal conductive lines to include a second height;
etching, by the fabrication system, the other of the at least one of the first plurality of metal conductive lines and the second plurality of metal conductive lines; and
disposing, by the fabrication system, a plurality of vias connecting the first level of interconnect wiring to the second level of interconnect wiring;
wherein the second height is different than the first height.

17. The method according to claim 16, wherein the second height is different than the first height by at least 25%.

18. The method according to claim 16, wherein the first height and the second height are optimized for at least one of resistance or capacitance for electrical connections with the first level of interconnect wiring and the second level of interconnect wiring.

19. The method according to claim 16, wherein the plurality of vias include a first group and a second group; the first group includes a first height; the second group includes second height; and the first height of the first group is different than the second height of the second group.

20. The method according to claim 16, wherein the first level of interconnect wiring is formed via a subtractive process; and the second level of interconnect wiring is formed via a damascene process.
